(19) United States
(12) Patent Application Publication
(10) Pub. No.: US 2025/0391309 A1
(43) Pub. Date: Dec. 25, 2025

(54) DISPLAY DEVICE AND DISPLAY SYSTEM INCLUDING THE SAME

(71) Applicant: SAMSUNG DISPLAY CO., LTD., YONGIN-SI (KR)

(72) Inventors: Jae Keun LIM, Yongin-si (KR); Hae Kwan SEO, Yongin-si (KR)

(21) Appl. No.: 19/206,648

(22) Filed: May 13, 2025

(30) Foreign Application Priority Data
Jun. 20, 2024 (KR) 10-2024-0080514
Sep. 11, 2024 (KR) 10-2024-0124169

(51) Int. Cl. G09G 3/20; G09G 3/3233; H10K 59/131; H10K 59/35

(52) U.S. Cl. CPC G09G 3/2074; G09G 3/3233; H10K 59/131; H10K 59/352; G09G 2300/0452; G09G 2300/0804; G09G 2300/0819; G09G 2300/0852; G09G 2310/06; G09G 2310/08; G09G 2330/023; G09G 2358/00; G09G 2380/10; H10K 59/353

(57) ABSTRACT

A display device includes a display panel including a narrow pixel, having a first light emitting unit, and a wide pixel, having a second light emitting unit. At least one channel is disposed on the display panel and provides a driving signal to the narrow pixel and the wide pixel. The first light emitting unit includes a (1_1)th sub-light emitting unit and a (1_3)th sub-light emitting unit, which are adjacent to each other in a first direction. The at least one channel includes a narrow channel which provides a first driving signal to the (1_1)th sub-light emitting unit and the (1_3)th sub-light emitting unit.

### CROSS-REFERENCE TO RELATED APPLICATION

The present application claims priority under 35 U.S.C. § 119 to Korean patent application No. 10-2024-0080514, filed in the Korean Intellectual Property Office on Jun. 20, 2024, and to Korean patent application No. 10-2024-0124169, filed in the Korean Intellectual Property Office on Sep. 11, 2024, the entire disclosures of which are herein incorporated by reference.

### TECHNICAL FIELD

The present disclosure relates to a display device and, more specifically, to a display device that includes both narrow and wide pixels and a display system including the same.

### DISCUSSION OF THE RELATED ART

While many early flat-screen display devices suffered from poor viewing angles, which made the display quality suffer as the user's head moved and the display device is observed from a slight angle, modern flat-panel display devices have been able to achieve good display quality from various angles.

However, in some cases, it may be desired that a display screen only be viewable from a direct head-on angle and that in the interests of maintaining privacy, viewability from other angles be limited. To accomplish this objective, users may install privacy screens over their electronic devices so as to reduce visibility from certain angles, however, such privacy screens may be difficult to remove and reinstall without damage.

### SUMMARY

A display device includes a display panel including a narrow pixel and a wide pixel. The narrow pixel includes a first light emitting unit and the wide pixel includes a second light emitting unit. At least one channel is disposed on the display panel. The at least one channel is configured to provide a driving signal to the narrow pixel and the wide pixel. The first light emitting unit includes a (1_1)th sub-light emitting unit and a (1_3)th sub-light emitting unit, which are adjacent to each other in a first direction. The at least one channel includes a narrow channel which provides a first driving signal to the (1_1)th sub-light emitting unit and the (1_3)th sub-light emitting unit.

The wide pixel may be configured to emit light in a normal mode, and the narrow pixel may be configured to emit light in a privacy mode.

The first driving signal may have a constant value in the privacy mode.

The second light emitting unit may include a (2_1)th sub-light emitting unit adjacent to the (1_3)th sub-light emitting unit in a second direction intersecting the first direction. The (2_1)th sub-light emitting unit may be configured to emit light based on a second driving signal that is different from the first driving signal.

The second light emitting unit may include a (2_3)th sub-light emitting unit adjacent to the (2_1)th sub-light emitting unit in the first direction. The at least one channel may include a wide channel which provides the second driving signal to the (2_1)th sub-light emitting unit and the (2_3)th sub-light emitting unit.

The display panel may include a substrate. A pixel circuit layer may be disposed on the substrate. The pixel circuit layer may include at least one transistor. A display element layer is disposed on the pixel circuit layer. The display element layer includes the first light emitting unit and the second light emitting unit. The pixel circuit layer may include a conductive terminal which electrically connects the at least one transistor to an anode of any one of the first light emitting unit and the second light emitting unit. The anode may be considered an anode electrode.

The conductive terminal may include a (1_1)th conductive terminal connected to a (1_1)th anode of the (1_1)th sub-light emitting unit and a (1_3)th conductive terminal connected to a (1_3)th anode of the (1_3)th sub-light emitting unit. In a plan view, the (1_1)th conductive terminal and the (1_3)th conductive terminal may overlap the narrow channel.

The (1_1)th anode may include a first anode bridge extending in a direction toward the (1_1)th conductive terminal.

The display device may further include a data driver configured to supply a data signal to the display panel. The at least one channel may be a data line extending from the data driver.

Each of the narrow pixel and the wide pixel may be arranged in a second direction intersecting the first direction.

The (1_1)th sub-light emitting unit and the (1_3)th sub-light emitting unit may emit light of a first color.

The narrow pixel may include a (1_2)th sub-light emitting unit and a (1_4)th sub-light emitting unit, which are adjacent to each other in a second direction intersecting the first direction. The (1_2)th sub-light emitting unit may emit light of a second color that is different from the first color, and the (1_4)th sub-light emitting unit may emit light of a third color that is different from the first color and the second color.

In a plan view, the (1_1)th sub-light emitting unit and the (1_3)th sub-light emitting unit may each have a rectangular shape, and the (1_2)th sub-light emitting unit and the (1_4)th sub-light emitting unit may each have a rhombic shape.

In a plan view, an area of the (1_4)th sub-light emitting unit may be wider than an area of the (1_2)th sub-light emitting unit, and the area of the (1_2)th sub-light emitting unit may be wider than an area of each of the (1_1)th sub-light emitting unit and the (1_3)th sub-light emitting unit.

The (1_1)th sub-light emitting unit may emit light of a second color, and the (1_3)th sub-light emitting unit may emit light of a third color that is different from the second color.

The narrow pixel may include a (1_2)th sub-light emitting unit and a (1_4)th sub-light emitting unit, which are adjacent to each other in the second direction. The (1_2)th sub-light emitting unit and the (1_4)th sub-light emitting unit may emit light of a first color that is different from the second color and the third color.

The (1_3)th anode may extend in an opposite direction of the first direction and the second direction to be in contact with the (1_3)th conductive terminal

A display system includes a processor and a display device configured to display an image based on input image data sent from the processor. The display device includes a display panel including a narrow pixel including a first light emitting unit, and a wide pixel including a second light emitting unit. At least one channel is disposed on the display panel. The at least one channel is configured to provide a driving signal to the narrow pixel and the wide pixel. The first light emitting unit includes a (1_1)th sub-light emitting unit and a (1_3)th sub-light emitting unit, which are adjacent to each other in a first direction. Wherein the at least one channel includes a narrow channel which provides a first driving signal to the (1_1)th sub-light emitting unit and the (1_3)th sub-light emitting unit.

The wide pixel may emit light in a normal mode, and the narrow pixel may emit light in a privacy mode.

The first driving signal may have a constant value in the privacy mode.

### BRIEF DESCRIPTION OF THE DRAWINGS

Example embodiments will now be described more fully hereinafter with reference to the accompanying drawings; however, they may be embodied in different forms and should not necessary be construed as limited to the embodiments set forth herein. Rather, these embodiments are provided so that this disclosure will be thorough and complete, and will fully convey the scope of the example embodiments to those skilled in the art.

While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like. It will be understood that when an element is referred to as being “between” two elements, it can be the only element between the two elements, or one or more intervening elements may also be present. Like reference numerals may refer to like elements throughout the specification and the figures.

FIG. 1 is a block diagram illustrating an embodiment of a display device.

FIG. 2 is a block diagram illustrating an embodiment of a sub-pixel.

FIG. 3 is a circuit diagram illustrating an embodiment of the sub-pixel.

FIG. 4 is a plan view illustrating an embodiment of a display panel shown in FIG. 1.

FIG. 5 is a cross-sectional view illustrating an embodiment of the display panel shown in FIG. 1.

FIG. 6 is a plan view illustrating an embodiment of pixels of a first area shown in FIG. 4.

FIG. 7 is a plan view illustrating a layout of an anode layer and conductive terminals, which are included in the pixel shown in FIG. 4.

FIG. 8 is a cross-sectional view illustrating a stacked relationship of the display panel shown in FIG. 6.

FIG. 9 is a view illustrating a driving signal applied to a narrow channel shown in FIG. 7.

FIG. 10 is a plan view illustrating an embodiment of the pixels of the first area shown in FIG. 4.

FIG. 11 is a plan view illustrating still an embodiment of the pixels of the first area shown in FIG. 4.

FIG. 12 is a plan view illustrating an embodiment of the pixels of the first area shown in FIG. 4.

FIG. 13 is a block diagram illustrating an embodiment of a display system.

FIG. 14 is a perspective view illustrating an application example of the display system shown in FIG. 13.

### DETAILED DESCRIPTION

Hereinafter, embodiments of the present disclosure will be described in more detail with reference to the accompanying drawings. The present disclosure is not necessarily limited to exemplary embodiments described herein, but may be embodied in various different forms. Rather, exemplary embodiments described herein are provided to thoroughly and completely describe the disclosed contents and to sufficiently transfer the ideas of the disclosure to a person of ordinary skill in the art.

In the entire specification, when an element is referred to as being “connected” or “coupled” to another element, it can be directly connected or coupled to the another element or be indirectly connected or coupled to the another element with one or more intervening elements interposed therebetween. It will be understood that when a component “includes” or “comprises” an element, unless there is another opposite description thereto, it should be understood that the component does not exclude another element but may further include another element. It will be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from the group consisting of X, Y, and Z” can be construed as X only, Y only, Z only, or any combination of two or more items X, Y, and Z (e.g., XYZ, XYY, YZ, ZZ).

It will be understood that, although the terms “first”, “second,” etc. may be used herein to describe various elements, these elements should not necessarily be limited by these terms. These terms are used to distinguish one element from another element. Thus, a “first” element discussed below could also be termed a “second” element without departing from the teachings of the present disclosure.

Spatially relative terms, such as “below,” “above,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the exemplary term, “above,” may encompass both an orientation of above and below. The apparatus may be otherwise oriented (e.g., rotated 90 degrees or at other orientations) and the spatially relative descriptors used herein interpreted accordingly.

In addition, the embodiments of the disclosure are described here with reference to schematic diagrams of ideal embodiments (and an intermediate structure) of the present disclosure, so that changes in a shape as shown due to, for example, manufacturing technology and/or a tolerance may be expected. Therefore, the embodiments of the present disclosure shall not necessarily be limited to the specific shapes of a region shown here, but include shape deviations caused by, for example, the manufacturing technology.

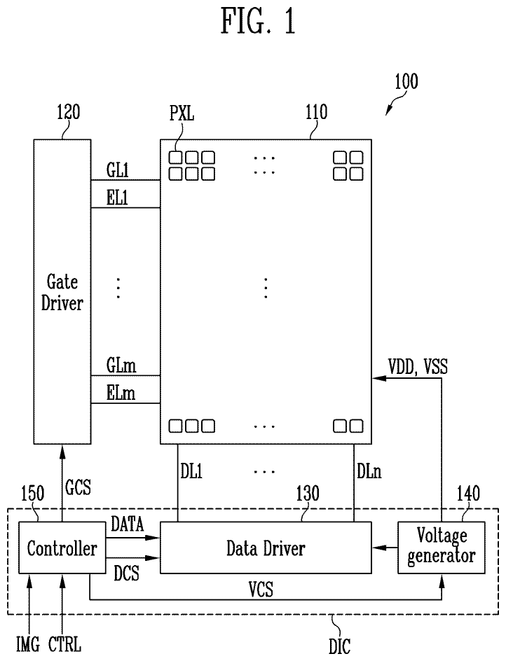

FIG. 1 is a block diagram illustrating an embodiment of a display device.

Referring to FIG. 1, the display device 100 may include a display panel 110, a gate driver 120, a data driver 130, a voltage generator 140, and a controller 150.

The display panel 110 may include pixels PXL. The pixels PXL may be connected to the gate driver 120 through first to m-th gate lines GL1 to GLm. The pixels PXL may be connected to the data driver 130 through first to n-th data lines DL1 to DLn.

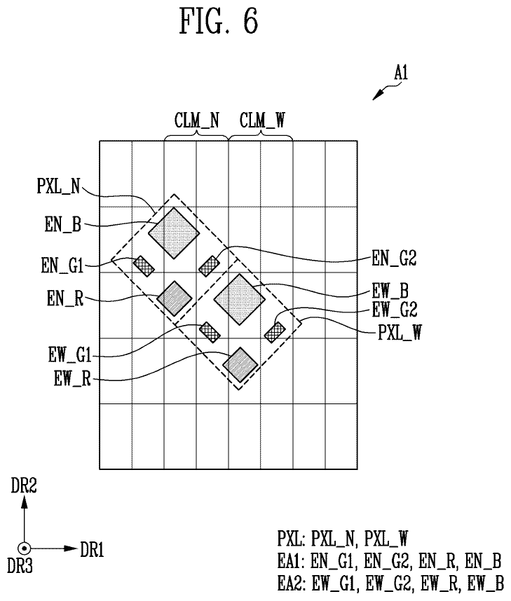

Each pixel PXL may be configured with a plurality of sub-pixels. Each of the sub-pixels may include at least one light emitting element configured to generate light. Accordingly, each of the sub-pixels may generate light of a specific color such as red, green, blue, cyan, magenta or yellow. In an embodiment, the display panel 110 may be a switchable display panel in which a switch between a normal mode and a privacy mode in which a viewing angle is limited is possible. As such, when the display panel 110 supports the privacy mode, the sub-pixels may include wide pixels emitting light in the normal mode and narrow pixels emitting light in the privacy mode. This will be described in detail later with reference to FIG. 6.

The gate driver 120 may be connected to the sub-pixels arranged in a row direction through the first to m-th gate lines GL1 to GLm. The gate driver 120 may output gate signals to the first to m-th gate lines GL1 to GLm in response to a gate control signal GCS. In an embodiment, the gate control signal GCS may include a start signal indicating a start of each frame, a horizontal synchronization signal for outputting gate signals in synchronization with timings at which data signals are applied, and the like.

In an embodiment, first to m-th emission control lines EL1 to ELm connected to the sub-pixels in the row direction may be further provided. The gate driver 120 may include an emission control driver configured to control the first to m-th emission control lines EL1 to ELm, and the emission control driver may operate under the control of the controller 150.

The gate driver 120 may be disposed at one side of the display panel 110. However, embodiments are not necessarily limited thereto. For example, the gate driver 120 may be divided into two or more drivers which are physically and/or logically divided, and these drivers may be disposed at one side of the display panel 110 and the other side of the display panel 110, which is opposite to the one side. As such, in accordance with embodiments, the gate driver 120 may be disposed in various forms at the periphery of the display panel 110.

The data driver 130 may be connected to the sub-pixels arranged in a column direction through the first to n-th data lines DL1 to DLn. The data driver 130 may receive image data DATA and a data control signal DCS from the controller 150. The data driver 130 may operate in response to the data control signal DCS. In an embodiment, the data control signal DCS may include a source start pulse, a source shift clock, a source output enable signal, and the like.

The data driver 130 may apply data signals having grayscale voltages corresponding to the image data DATA to the first to n-th data lines DL1 to DLn by using voltages from the voltage generator 140. When a gate signal is applied to each of the first to m-th gate lines GL1 to GLm, data signals corresponding to the image data DATA may be applied to the data lines DL1 to DLn. Accordingly, corresponding sub-pixels may generate light corresponding to the data signals. Accordingly, an image may be displayed on the display panel 110.

In an embodiment, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate voltages and provide the generated voltages to components of the display device 100. For example, the voltage generator 140 may be configured to generate a plurality of voltages by receiving an input voltage from beyond the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels. The first power voltage VDD may have a relatively high voltage level, and the second power voltage VSS may have a voltage level lower than the voltage level of the first power voltage VDD. In an embodiment, the first power voltage VDD or the second power voltage VSS may be provided by an external device of the display device 100.

The voltage generator 140 may generate various voltages. For example, the voltage generator 140 may generate an initialization voltage applied to the sub-pixels. For example, a predetermined reference voltage may be applied to the first to n-th data lines DL1 to DLn in a sensing operation for sensing electrical characteristics of transistors and/or light emitting elements of the sub-pixels, and the voltage generator 140 may generate the reference voltage.

The controller 150 may control overall operations of the display device 100. The controller 150 may receive externally supplied input image data IMG and a control signal CTRL for controlling display thereof. The controller 150 may provide the gate control signal GCS, the data control signal DCS, and the voltage control signal VCS in response to the control signal CTRL.

The controller 150 may convert the input image data IMG to be suitable for the display device 100 or the display panel 110, thereby outputting the image data DATA. In an embodiment, the controller 150 may align the input image data IMG to be suitable for the sub-pixels in units of rows, thereby outputting the image data DATA.

Two or more components among the data driver 130, the voltage generator 140, and the controller 150 may be mounted on one integrated circuit. As shown in FIG. 1, the data driver 130, the voltage generator 140, and the controller 150 may be included in a driver integrated circuit DIC. The data driver 130, the voltage generator 140, and the controller 150 may be components functionally divided in one driver integrated circuit DIC. In an embodiment, at least one of the data driver 130, the voltage generator 140, and the controller 150 may be provided as a component distinguished from the driver integrated circuit DIC.

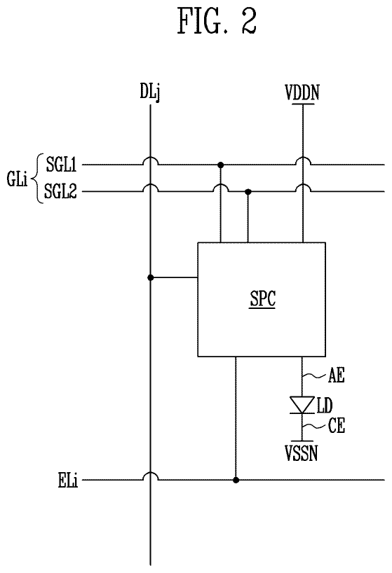

FIG. 2 is a block diagram illustrating an embodiment of a sub-pixel.

In FIG. 2, a sub-pixel arranged on an i-th row (where i is an integer greater than or equal to 1 and smaller than or equal to m) and a j-th column (where j is an integer greater than or equal to 1 and smaller than or equal to n) is exemplarily illustrated.

Referring to FIG. 2, the sub-pixel may include a pixel circuit SPC and a light emitting element LD. The light emitting element LD may be connected between a first power voltage node VDDN and a second power voltage node VSSN. The first power voltage node VDDN may be a node which the first power voltage VDD shown in FIG. 1 is transferred, and the second power voltage node VDDN may be a node through which the second power voltage VSS shown in FIG. 1 is transferred.

An anode AE of the light emitting element LD may be connected to the first power voltage node VDDN through the pixel circuit SPC, and a cathode CE of the light emitting element LD may be connected to the second power voltage node VSSN. The cathode may be considered a cathode electrode. For example, the anode AE of the light emitting element LD may be connected to the first power voltage node VDDN through one or more transistors included in the pixel circuit SPC.

The pixel circuit SPC may be connected to an i-th gate line GLi among the first to m-th gate lines GL1 to GLm shown in FIG. 1, an i-th emission control line ELi among the first to m-th emission control lines EL1 to ELm shown in FIG. 1, and a j-th data line DLj among the first to n-th data lines DL1 to DLn shown in FIG. 1. The pixel circuit SPC may be configured to control the light emitting element LD according to signals received through these signal lines.

The pixel circuit SPC may operate in response to a gate signal received through the i-th gate line GLi. The i-th gate line GLi may include one or more sub-gate lines. In an embodiment, as shown in FIG. 2, the i-th gate line GLi may include first and second sub-gate lines SGL1 and SGL2. The pixel circuit SPC may operate in response to gate signals received through the first and second sub-gate lines SGL1 and SGL2. As such, when the i-th gate line GLi includes two or more sub-gate lines, the pixel circuit SPC may operate in response to gate signals received through the corresponding sub-gate lines.

The pixel circuit SPC may operate in response to an emission control signal received through the i-th emission control line ELi. In an embodiment, the i-th emission control line ELi may include one or more sub-emission control lines. When the i-th emission control line ELi includes two or more sub-emission control lines, the pixel circuit SPC may operate in response to emission control signals received through the corresponding sub-emission control lines.

The pixel circuit SPC may receive a data signal through the j-th data line DLj. The pixel circuit SPC may store a voltage corresponding to the data signal in response to at least one of the gate signals received through the first and second sub-gate lines SGL1 and SGL2. The pixel circuit SPC may adjust a current flowing from the first power voltage node VDDN to the second power voltage node VSSN through the light emitting element LD according to the stored voltage in response to the emission control signal received through the i-th emission control line ELi. Accordingly, the light emitting element LD may generate light with a luminance corresponding to the data signal.

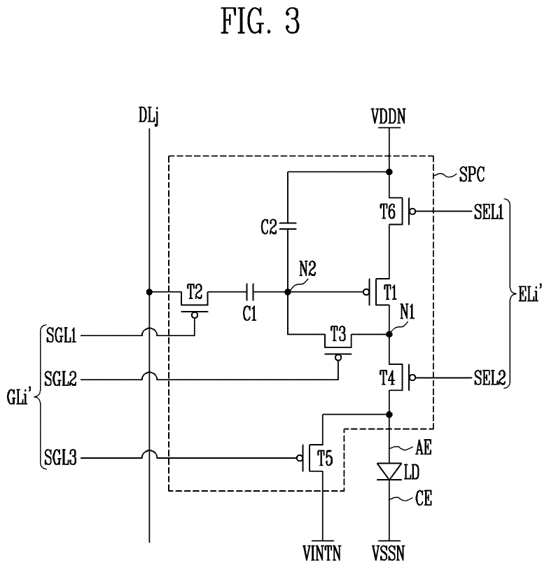

FIG. 3 is a circuit diagram illustrating an embodiment of the sub-pixel.

Referring to FIG. 3, a sub-pixel may include a pixel circuit SPC and a light emitting element LD.

The pixel circuit SPC may be connected to an i-th gate line GLi′, an i-th emission control line ELi′, and a j-th data line DLj. When comparing the i-th gate line GLi′ with the i-th gate line GLi shown in FIG. 2, the i-th gate line GLi′ may further include a third sub-gate line SGL3. When comparing the i-th emission control line ELi′ with the i-th emission control line ELi shown in FIG. 2, the i-th emission control line ELi′ may include a first sub-emission control line SEL1 and a second sub-emission control line SEL2.

The pixel circuit SPC may include first to sixth transistors T1 to T6 and first and second capacitors C1 and C2.

The first transistor T1 may be connected between a first power voltage node VDDN and a first node N1. A gate of the first transistor T1 may be connected to a second node N2, and accordingly, the first transistor T1 may be turned on according to a voltage level of the second node N2. The first transistor T1 may be designated as a driving transistor.

The second transistor T2 may be connected between the j-th data line DLj and the second node N2. A gate of the second transistor T2 may be connected to a first sub-gate line SGL1, and accordingly, the second transistor T2 may be turned on in response to a gate signal of the first sub-gate line SGL1. The second transistor T2 may be designated as a switching transistor.

The third transistor T3 may be connected between the first node N1 and the second node N2. A gate of the third transistor T3 may be connected to a second sub-gate line SGL2, and accordingly, the third transistor T3 may be turned on in response to a gate signal of the second sub-gate line SGL2.

The fourth transistor T4 may be connected between the first node N1 and an anode AE of the light emitting element LD. A gate of the fourth transistor T4 may be connected to the second sub-emission control line SEL2, and accordingly, the fourth transistor T4 may be turned on in response to an emission control signal of the second sub-emission control line SEL2.

The fifth transistor T5 may be connected between the anode AE of the light emitting element LD and an initialization voltage node VINTN. The initialization voltage node VINTN may be configured to transfer an initialization voltage. In an embodiment, the initialization voltage may be provided by the voltage generator 140 shown in FIG. 1. In an embodiment, the initialization voltage may be provided by an external device of the display device 100. A gate of the fifth transistor T5 may be connected to the third sub-gate line SGL3, and accordingly, the fifth transistor T5 may be turned on in response to a gate signal of the third sub-gate line SGL3.

The sixth transistor T6 may be connected between the first power voltage node VDDN and the first transistor T1. A gate of the sixth transistor T6 may be connected to the first sub-emission control line SEL1, and accordingly, the sixth transistor T6 may be turned on in response to an emission control signal of the first sub-emission control line SEL1.

The first capacitor C1 may be connected between the second transistor T2 and the second node N2. The second capacitor C2 may be connected between the first power voltage node VDDN and the second node N2.

As such, the pixel circuit SPC may include the first to sixth transistors T1 to T6 and the first and second capacitors C1 and C2. However, embodiments are not necessarily limited thereto. The pixel circuit SPC may be implemented as any one of various types of circuits each including a plurality of transistors and one or more capacitors. For example, the pixel circuit SPC may include two transistors and one capacitor. In accordance with embodiments of the pixel circuit SPC, the number of sub-gate lines included in the i-th gate line GLi′ and the number of sub-emission control lines included in the i-th emission control line ELi′ may vary.

The first to sixth transistors T1 to T6 may be P-type transistors. Each of the first to sixth transistors T1 to T6 may be a Metal Oxide Silicon Field Effect Transistor (MOSEFT). However, embodiments are not necessarily limited thereto. For example, at least one of the first to sixth transistors T1 to T6 may be replaced with an N-type transistor.

In an embodiment, the first to sixth transistors T1 to T6 may include an amorphous silicon semiconductor, a monocrystalline silicon semiconductor, a polycrystalline silicon semiconductor, an oxide semiconductor, and the like.

The light emitting element LD may include the anode AE, a cathode CE, and a light emitting layer. The light emitting layer may be disposed between the anode AE and the electrode CE. After a data signal transferred through the j-th data line DLj is reflected on a voltage of the second node N2, the fourth and sixth transistors T4 and T6 may be turned on when the emission control signals of the first and second sub-emission control lines SEL1 and SEL2 are enabled to a low level. The first transistor T1 may be turned on according to the voltage of the second node N2, and accordingly, a current may flow from the first power voltage node VDDN to a second power voltage node VSSN. The light emitting element LD may emit light according to an amount of the current flowing from the first power voltage node VDDN to the second power voltage node VSSN.

In FIG. 3, a pixel circuit diagram is illustrated as an example. However, the present disclosure is not necessarily limited thereto. For example, any circuit is not necessarily limited thereto as long as the circuit can driver a wide pixel PXL_W and/or a narrow pixel PXL_N of the display panel 110 in accordance with the embodiment of the present disclosure.

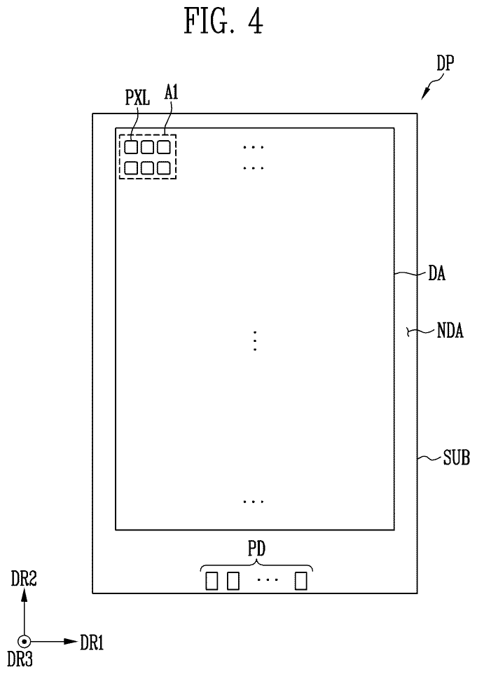

FIG. 4 is a plan view illustrating an embodiment of the display panel shown in FIG. 1.

Referring to FIG. 4, the embodiment of the display panel 110 shown in FIG. 1 may include a display area DA and a non-display area NDA. The display panel DP may display an image through the display area DA. The non-display area NDA may be disposed at the periphery of the display area DA, may be proximate to the display area DA, and may surround the display area DA on at least two opposite sides thereof.

The display panel DP may include a substrate SUB, pixels PXL, and pads PD. The pixels PXL may be disposed in the display area DA on the substrate SUB. The pixels PXL may be arranged in a matrix form along a first direction DR1 and a second direction DR2 intersecting the first direction DR1. However, embodiments are not necessarily limited thereto. The first direction DR1 may be a row direction, and the second direction DR2 may be a column direction.

A component for controlling the pixels PXL may be disposed in the non-display area NDA on the substrate SUB. For example, lines such as the first to m-th gate lines GL1 to GLm and the first to n-th data lines DL1 to DLn, which are shown in FIG. 1, may be disposed in the non-display area NDA.

At least one of the gate driver 120, the data driver 130, the voltage generator 140, and the controller 150, which are shown in FIG. 1, may be integrated in the non-display area NDA of the display panel DP. In an embodiment, the gate driver 120 shown in FIG. 1 may be mounted on the display panel DP, and are disposed in the non-display area NDA. In an embodiment, the gate driver 120 may be implemented as an integrated circuit distinguished from the display panel DP.

The pads PD may be disposed in the non-display area NDA on the substrate SUB. The pads PD may be electrically connected to the pixels PXL through the lines. For example, the pads PD may be connected to the pixels PXL through the first to n-th data lines DL1 to DLn.

The pads PD may interface the display panel DP with other components of the display device 100 (see FIG. 1). In an embodiment, voltages and signals, which are necessary for operations of components included in the display panel DP, may be provided from the driver integrated circuit DIC shown in FIG. 1 through the pads PD. For example, the first to n-th data lines DL1 to DLn may be connected to the driver integrated circuit DIC through the pads PD. For example, the first and second power voltages VDD and VSS may be received from the driver integrated circuit DIC through the pads PD. When the gate driver 120 is mounted in the display panel DP, the gate control signal GCS may be transmitted from the driver integrated circuit DIC to the gate driver 120 through the pads PD.

In an embodiment, a circuit board may be electrically connected to the pads PD, using a conductive adhesive such as an anisotropic conductive film. The circuit board may be a flexible printed circuit board (FPCB) or a flexible film, which has a flexible material. The driver integrated circuit DIC may be mounted on the circuit board to be electrically connected to the pads PD.

In an embodiment, the display area DA may have various shapes. The display area DA may have a closed-loop shape including linear sides and/or curved sides. For example, the display area DA may have shapes such as a polygon, a circle, a semicircle, and an ellipse.

In an embodiment, the display panel DP may have a flat display surface. In an embodiment, the display panel DP may at least partially have a round display surface. In an embodiment, the display panel DP may be bendable, foldable or rollable to a noticeable extent without cracking or otherwise sustaining damage. The display panel DP and/or the substrate SUB may include various flexible materials.

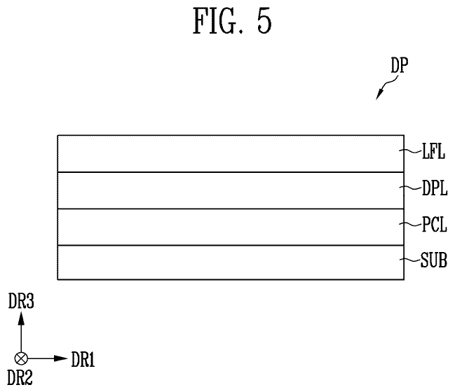

FIG. 5 is a cross-sectional view illustrating an embodiment of the display panel shown in FIG. 1.

Referring to FIG. 5, a display panel DP may include a substrate SUB, and a pixel circuit layer PCL, a display element layer DPL, and a light functional layer LFL, which are sequentially stacked in a third direction DR3 intersecting the first and second directions DR1 and DR2 on the substrate SUB.

The substrate SUB may be made of an insulative material such as glass or resin. For example, the substrate SUB may include a glass substrate. In an example, the substrate SUB may include polyimide (PI) substrate. In an example, the substrate SUB may include a silicon wafer substrate formed using a semiconductor process.

In embodiments, the substrate SUB may be made of a flexible material to be curvable or foldable, and have a single-layer structure or a multi-layer structure. For example, the flexible material may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not necessarily limited thereto.

The pixel circuit layer PCL may be disposed on the substrate SUB. The pixel circuit layer PCL may include insulating layers, and semiconductor patterns and conductive patterns, which are disposed between the insulating layers. The conductive patterns of the pixel circuit layer PCL may serve as circuit elements, lines, and the like.

The circuit elements of the pixel circuit layer PCL may constitute a pixel circuit SPC (see FIG. 2) of each of the sub-pixels shown in FIG. 3. For example, the circuit elements of the pixel circuit layer PCL may be provided as transistors and one or more capacitors of the pixel circuit SPC.

The lines of the pixel circuit layer PCL may include lines connected to each of the sub-pixels. The lines of the pixel circuit layer PCL may include various signal lines and/or various voltage lines, which are necessary for driving the display element layer DPL.

The display element layer DPL may be disposed on the pixel circuit layer PCL. The display element layer DPL may include light emitting elements of the sub-pixels.

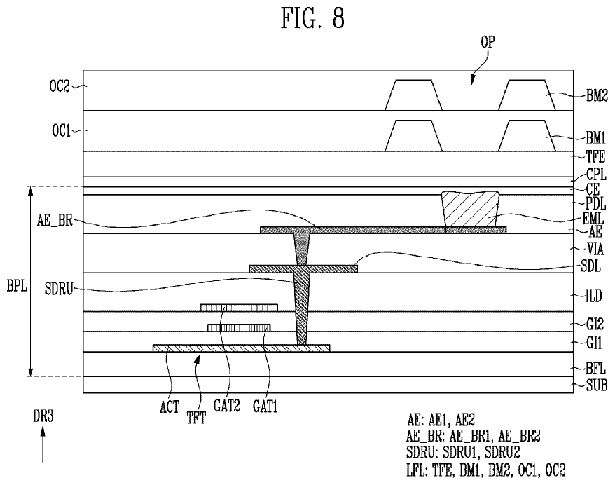

The light functional layer LFL may be disposed on the display element layer DPL. The light functional layer LFL may control at least some of lights output from the display element layer DPL. For example, the light functional layer LFL may include a first light blocking layer BM1 (see FIG. 8) and a second light blocking layer BM2 (see FIG. 8). Accordingly, the light blocking layer LFL absorbs at least some of lights output from the display element layer DPL, so as not to be viewed by a user of the display device 100 (see FIG. 1). This will be described in detail later with reference to FIG. 8.

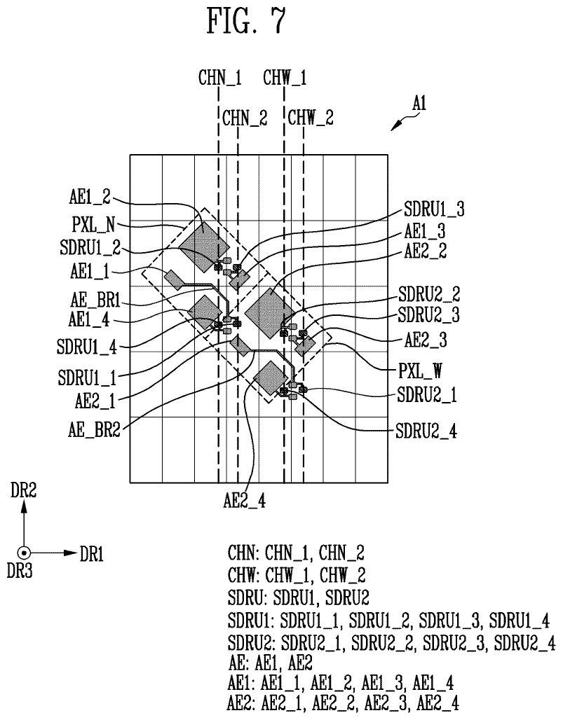

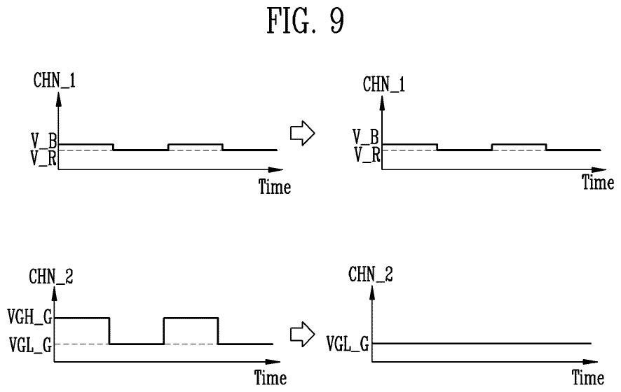

FIG. 6 is a plan view illustrating an embodiment of pixels of a first area A1 shown in FIG. 4. FIG. 7 is a plan view illustrating a layout of an anode layer and conductive terminals, which are included in the pixel shown in FIG. 4. FIG. 8 is a cross-sectional view illustrating a stacked relationship of the display panel shown in FIG. 6. FIG. 9 is a view illustrating a driving signal applied to a narrow channel shown in FIG. 7.

Referring to FIG. 6, a pixel PXL may include a narrow pixel PXL_N and a wide pixel PXL_W. The narrow pixel PXL_N may be a pixel PXL having a viewing angle narrower than a viewing angle of the wide pixel PXL_W. In an example, the wide pixel PXL_W may emit light in the normal mode, and the narrow pixel PXL_N emits light in the privacy mode but might not emit light in the normal mode. Accordingly, an image having a normal viewing angle is displayed in the normal mode, and an image having a relatively limited viewing angle is displayed in the privacy mode, thereby preventing an image from being viewed in a specific direction, e.g., at a side of the display panel DP. While the narrow pixel PXL_N alternately emits light according to a driving mode, power consumption of the display panel DP (see FIG. 4) may be increased. However, the operations in the normal mode and the privacy mode are not necessarily limited thereto. In some embodiments, both the wide pixel PXL_W and the narrow pixel PXL_N may emit light in the privacy mode.

Each of the wide pixel PXL_W and the narrow pixel PXL_N may have a rhombic shape. However, this is merely illustrative, and the present disclosure is not necessarily limited thereto. For example, each of the wide pixel PXL_W and the narrow pixel PXL_N may have a quadrangular shape.

The wide pixel PXL_W and the narrow pixel PXL_N may include a first light emitting unit EA1 and a second light emitting unit EA2, respectively. A plurality of light emitting units EA1 and EA2 may be defined as not only an area in which a pixel electrode is exposed by an opening of a pixel defining layer, in a cross-sectional view, but also an area in which the exposed pixel electrode and a light emitting layer overlap each other, in a cross-sectional view.

Each of first light emitting units EA1 may include a (1_1)th sub-light emitting unit EN_G1, a (1_2)th sub-light emitting unit EN_B, a (1_3)th sub-light emitting unit EN_G2, and a (1_4)th sub-light emitting unit EN_R. Each of second light emitting units EA2 may include a (2_1)th sub-light emitting unit EW_G1, a (2_2)th sub-light emitting unit EW_B, a (2_3)th sub-light emitting unit EW_G2, and a (2_4)th sub-light emitting unit EW_R.

The (1_1)th sub-light emitting unit EN_G1, the (1_3)th sub-light emitting unit EN_G2, the (2_1)th sub-light emitting unit EW_G1, and the (2_3)th sub-light emitting unit EW_G2 may emit green light. The (1_2)th sub-light emitting unit EN_B and the (2_2)th sub-light emitting unit EW_B may emit blue light. The (1_4)th sub-light emitting unit EN_R and the (2_4)th sub-light emitting unit EW_R may emit red light. However, this is merely illustrative, and the present disclosure is not necessarily limited thereto.

The (1_1)th sub-light emitting unit EN_G1 and the (1_3)th sub-light emitting unit EN_G2 may be adjacent to each other in the first direction DR1. The (1_1)th sub-light emitting unit EN_G1 and the (1_3)th sub-light emitting unit EN_G2 may be symmetrically disposed. For example, in a plan view, the (1_1)th sub-light emitting unit EN_G1 and the (1_3)th sub-light emitting unit EN_G2 have a rectangular shape, and are symmetrically disposed with respect to the second direction DR2. In a plan view, the (1_1)th sub-light emitting unit EN_G1 and the (1_3)th sub-light emitting unit EN_G2 may have the same size. The (1_1)th sub-light emitting unit EN_G1 may have a rectangular shape extending in a direction between the opposite direction of the first direction DR1 and the second direction DR2, and the (1_3)th sub-light emitting unit EN_G2 may have a rectangular shape extending in a direction between the first direction DR1 and the second direction DR2.

The (1_2)th sub-light emitting unit EN_B and the (1_4)th sub-light emitting unit EN_R may be adjacent to each other in the second direction DR2. In a plan view, a size of the (1_2)th sub-light emitting unit EN_B may be larger than the (1_4)th light emitting unit EN_R. However, the sizes and shapes of the (1_1) to (1_4) light emitting units are not necessarily limited to the embodiment exemplified in FIG. 6, and may be modified to have various sizes and various shapes.

The (2_1)th sub-light emitting unit EW_G1 and the (2_3)th sub-light emitting unit EW_G2 may be adjacent to each other in the first direction DR1. The (2_1)th sub-light emitting unit EW_G1 and the (2_3)th sub-light emitting unit EW_G2 may be symmetrically disposed. For example, in a plan view, the (2_1)th sub-light emitting unit EW_G1 and the (2_3)th sub-light emitting unit EW_G2 may have a rectangular shape, and are symmetrically disposed with respect to the second direction DR2. In a plan view, the (2_1)th sub-light emitting unit EW_G1 and the (2_3)th sub-light emitting unit EW_G2 may have the same size.

The (2_2)th sub-light emitting unit EW_B and the (2_4)th sub-light emitting unit EW_R may be adjacent to each other in the second direction DR2. In a plan view, a size of the (2_2)th sub-light emitting unit EW_B may be larger than a size of the (2_4)th sub-light emitting unit EW_R. However, the sizes and shapes of the (2_1)th to (2_4)th sub-light emitting units are not necessarily limited to the embodiment exemplified in FIG. 6, and may be modified to have various sizes and various shapes.

The wide pixel PXL_W and the narrow pixel PXL_N may be provided in plural to be arranged on the display panel DP. For example, for convenience of description, a single wide pixel PXL_W and a single narrow pixel PXL_N are illustrated in FIG. 6, but each of a plurality of wide pixels PXL_W and a plurality of narrow pixels PXL_N may be arranged in the second direction DR2.

In FIG. 6, it is illustrated that the wide pixel PXL_W and the narrow pixel PXL_N have the same size in a plan view. However, the present disclosure is not necessarily limited thereto. For example, a size of the wide pixel PXL_W in a plan view may be larger than a size of the narrow pixel PXL_N in a plan view.

In FIG. 7, a connection relationship of anodes, conductive terminals, narrow channels, and second channels of the pixels shown in FIG. 6 is schematically illustrated. For convenience of description, illustration of other components is not illustrated, but this is not necessarily limited as shown in FIG. 7.

Referring to FIGS. 6 and 7, at least a portion of the narrow pixel PXL_N may overlap a first column CLM_N. At least a portion of the wide pixel PXL_W may overlap a second column CLM_W. The first column CLM_N and the second column CLM_W may be a column on which at least one of a plurality of data lines DL1 to DLn is disposed. For convenience of description, a single first column CLM_N and a single second column CLM_W are illustrated in FIG. 6, but the present disclosure is not necessarily limited thereto. For example, the first column CLM_N and the second column CLM_W may be alternately disposed in the first direction DR1 on the first area A1 (or the display panel DP).

The first column CLM_N may include narrow channels CHN extending in the second direction DR2. The second column CLM_W may include wide channels CHW extending in the second direction DR2. The narrow channels CHN and the wide channels CHW may correspond to any one of the plurality of data lines DL1 to DLn. However, this is merely illustrative, and any line is not necessarily limited thereto as long as the line provides a signal for driving the narrow pixel PXL_N and the wide pixel PXL_W.

The narrow channels CHN may be electrically connected to anode AE through conductive terminals SDRU. For example, in a plan view, the first anode bridge AE_BR1 may extend in the first direction DR1 and the second direction DR2, and connect a (1_1)th conductive terminal SDRU1_1 and a (1_1)th anode AE1_1. A second narrow channel CHN_2 may be electrically connected to the (1_1)th anode AE1_1 via the (1_1)th conductive terminal SDRU1_1 and the first anode bridge AE_BR1.

In some embodiments, a (1_2)th anode AE1_2 may be connected to a (1_2)th conductive terminal SDRU1_2. Accordingly, the (1_2)th anode AE1_2 may be connected to a first narrow channel CHN_1. A (1_3)th anode AE1_3 may be connected to a (1_3)th conductive terminal SDRU1_3. Accordingly, the (1_3)th anode AE1_3 may be connected to the second narrow channel CHN_2. A (1_4)th anode AE1_4 may be connected to a (1_4)th conductive terminal SDRU1_4. Accordingly, the (1_4)th anode AE1_4 may be connected to the first narrow channel CHN_1.

The wide channels CHW may be electrically connected to anode AE through conductive terminals SDRU. For example, in a plan view, a second anode bridge AE_BR2 may extend in the first direction DR1 and the second direction DR2, and connect a (2_1)th conductive terminal SDRU2_1 and a (2_1)th anode AE2_1. A second wide channel CHW_2 may be electrically connected to the (2_1)th anode AE2_1 via the (2_1)th conductive terminal SDRU2_1 and the second anode bridge AE_BR2.

In some embodiments, a (2_2)th anode AE2_2 may be connected to a (2_2)th conductive terminal SDRU2_2. Accordingly, the (2_2)th anode AE2_2 may be connected to a first wide channel CHW_1. A (2_3)th anode AE2_3 may be connected to a (2_3)th conductive terminal SDRU2_3. Accordingly, the (2_3)th anode AE2_3 may be connected to the second wide channel CHW_2. A (2_4)th anode AE2_4 may be connected to a (2_4)th conductive terminal SDRU2_4. Accordingly, the (2_4)th anode AE2_4 may be connected to the first wide channel CHW_1.

Referring to FIG. 8, a backplane layer BPL may be disposed on a substrate SUB.

The backplane layer BPL shown in FIG. 8 may be a layer including the pixel circuit layer PCL and the display element layer DPL, which are shown in FIG. 5. To the extent that an element is not described in detail with respect to this figure, it may be understood that the element is at least similar to a corresponding element that has been described elsewhere within the present disclosure.

The backplane layer BPL may have a form in which at least a portion is patterned in a structure in which a buffer layer, an active layer ACT, a first gate insulating layer GI1, a first gate electrode layer GAT1, a second gate insulating layer GI2, a second gate electrode layer GAT2, an interlayer insulating layer ILD, a conductive layer SDL, and a via layer VIA are sequentially stacked.

As described with reference to FIG. 3, a pixel circuit SPC (see FIG. 3) of each of first to third sub-pixels may include transistors and one or more capacitors. The semiconductor patterns and the conductive patterns of the pixel circuit layer PCL may serve as the transistors and the capacitors of the pixel circuit SPC. In addition, the conductive patterns of the pixel circuit layer PCL may further serve as, for example, the first to m-th gate lines GL1 to GLm, the first to n-th data lines DL1 to DLn, power lines, and pixel circuit control lines, which are shown in FIG. 1.

For example, the above-described electrode layers may be patterned according to one structure, to form a pixel circuit. For example, a portion of the active layer ACT, a portion of the first gate electrode layer GAT1, and a portion of the conductive layer SDL may form a transistor TFT. A conductive terminal SDRU may be any one of a source electrode and a drain electrode.

The buffer layer BFL may be disposed on one surface of the substrate SUB. The buffer layer BFL may prevent an impurity from being diffused into the circuit elements and the lines, which are included in the pixel circuit layer PCL (see FIG. 5). The buffer layer BFL may include an inorganic insulating layer including an inorganic material. In embodiments, the buffer layer BFL may include at least one of silicon nitride (SiNₓ), silicon oxide (SiOₓ), silicon oxynitride (SiOₓN_{y}), and a metal oxide such as aluminum oxide (AlOₓ). The buffer layer BFL may be provided as a single layer or a multi-layer. When the buffer layer BFL is provided as the multi-layer, layers of the multi-layer may be formed of the same material or be formed of different materials.

In embodiments, one or more barrier layers may be disposed between the substrate SUB and the buffer layer BFL. Each of the barrier layers may include polyimide.

The transistor TFT may be disposed on the buffer layer BFL. The transistor TFT may be any one of the transistors of the pixel circuit SPC. For example, the transistor TFT may be understood as a transistor connected to an anode AE among the transistors of the pixel circuit SPC.

The transistor TFT may include the active layer ACT, the first gate layer GAT1, and the conductive terminal SDRU. The conductive terminal SDRU may be any one of the source electrode and the drain electrode. A conductive terminal (or one terminal) different from the conductive terminal SDRU may exist, which constitutes the other of the source electrode and the drain electrode.

The active layer ACT may include a semiconductor. For example, the active layer ACT may include at least one selected from the group consisting of poly-silicon, Low Temperature Polycrystalline Silicon (LTPS), amorphous silicon, and an oxide semiconductor. The active layer ACT may include an inorganic material. In some embodiments, the inorganic material may include at least one selected from the group consisting of silicon nitride (SiNₓ), aluminum nitride (AlNₓ), titanium nitride (TiNₓ), silicon oxide (SiOₓ), aluminum oxide (AlOₓ), titanium oxide (TiOₓ), silicon oxycarbide (SiOₓC_{y}), and silicon oxynitride (SiOₓN_{y}). However, the present disclosure is not necessarily limited thereto.

The first gate insulating layer GI1, the second gate insulating layer GI2, and the interlayer insulating layer ILD may be disposed over the active layer ACT. The first gate insulating layer GI1, the second gate insulating layer GI2, and the interlayer insulating layer ILD may electrically separate, from each other, conductive patterns and/or semiconductor patterns, which are disposed between the first gate insulating layer GI1, the second gate insulating layer GI2, and the interlayer insulating layer ILD. For example, the first gate insulating layer GI1 may be disposed between the active layer ACT and the first gate layer GAT such that first gate layer GAT1 is spaced apart from the active layer ACT. For convenience of description, in FIG. 8, it is illustrated that the first gate insulating layer GII and the second gate insulating layer GI2 are components separate from each other. However, the first gate insulating layer GI1 and the second gate insulating layer GI2 may be included in the interlayer insulating layer ILD.

The first gate layer GAT1 and the second gate layer GAT2 may overlap a channel region of the active layer ACT. In an embodiment, the first gate layer GAT1 and the second gate layer GAT2 may be provided as a single layer including at least one material among copper (Cu), molybdenum (Mo), tungsten (W), aluminum neodymium (AlNd), titanium (Ti), aluminum (Al), and silver (Ag). In an embodiment, the first gate layer GAT1 and the second gate layer GAT2 may be provided as a multi-layer including at least one material among molybdenum (Mo), titanium (Ti), copper (Cu), aluminum (Al), and silver (Ag), which are low resistance materials.

In an embodiment, the buffer layer BFL, the first gate insulating layer GI1, the second gate insulating layer GI2, and the interlayer insulating layer ILD may include an inorganic material. In an embodiment, the first and second gate layers GAT1 and GAT2, the conductive layer SDL, and the conductive terminal SDRU may include a conductive material.

The conductive terminal SDRU may penetrate the interlayer insulating layer ILD. Accordingly, the conductive terminal SDRU may be in contact with the active layer ACT. The conductive terminal SDRU may include at least one material among copper (Cu), molybdenum (Mo), tungsten (W), aluminum neodymium (AlNd), titanium (Ti), aluminum (Al), and silver (Ag). Although the conductive terminal SDRU is illustrated as separate electrodes electrically connected to the active layer ACT, embodiments are not necessarily limited thereto.

The conductive terminal SDRU may be electrically connected to a light emitting element LD through a connection means such as an anode bridge electrode AE_BR disposed on at least one of interlayer insulating layers ILD. For example, the conductive terminal SDRU may be connected to an anode AE through the anode bridge electrode AE_BR. The anode bridge electrode AE_BR shown in FIG. 8 may be any one of the first anode bridge AE_BR1 and the second anode bridge AE_BR2, which are shown in FIG. 7. Also, the anode bridge electrode AE_BR shown in FIG. 8 may be any one of the (1_1)th conductive terminal SDRU1_1 and the (2_1)th conductive terminal SDRU2_1, which are shown in FIG. 7.

The anode bridge electrode AE_BR may include at least one material among copper (Cu), molybdenum (Mo), tungsten (W), aluminum neodymium (AlNd), titanium (Ti), aluminum (Al), and silver (Ag). However, this is merely illustrative, and the present disclosure is not necessarily limited thereto.

The number and materials of conductive layers, insulating layers, and via layers, which form the backplane layer BPL, are not necessarily limited to the above-described example, and may be variously changed.

The via layer VIA may be disposed on the interlayer insulating layer ILD. The via layer VIA may include an organic material. The via layer VIA may cover components under the via layer VIA.

The via layer VIA may include an inorganic insulating layer including an inorganic material and/or an organic insulating layer including an organic material. The inorganic insulating layer may include, for example, at least one of silicon oxide (SiOₓ), silicon nitride (SiNₓ), silicon oxynitride (SiOₓN_{y}), and a metal oxide such as aluminum oxide (AlOₓ). The organic insulating layer may include, for example, at least one of acrylic resin, epoxy resin, phenolic resin, polyamide resin, polyimide resin, unsaturated polyester resin, poly-phenylene ether resin, poly-phenylene sulfide resin, and benzocyclobutene resin.

The via layer VIA may include the same material as any one of the interlayer insulating layers ILD, but embodiments are not necessarily limited thereto. The via layer VIA may be provided as a single layer, but be provided as a multi-layer.

A light emitting layer EML may be electrically connected to the anode AE and a cathode CE. The light emitting layer EML, the anode AE, and the cathode CE may constitute the light emitting element LD. The light emitting layer EML may include a hole transport are a hole transport region, a light emitting layer, and an electron transport region, which are sequentially stacked. The light emitting layer EML shown in FIG. 8 may correspond to any one of the plurality of light emitting units EA1 and EA2 shown in FIG. 6. Also, the light emitting layer EML shown in FIG. 8 may be any one of the plurality of anodes AE shown in FIG. 7. In some embodiments, the anode AE, the light emitting layer EML, and the cathode CE may constitute the light emitting element LD (see FIGS. 2 and 3).

A pixel defining layer PDL may define an area in which the light emitting element LD is defined. The pixel defining layer PDL may be formed, including polyacrylate resin or polyimide resin. Alternatively, the pixel defining layer PDL may be formed of an inorganic material. For example, the pixel defining layer PDL may be formed, including silicon nitride, silicon oxide, silicon oxynitride, and the like.

A capping layer CPL may be disposed over the cathode CE. The capping layer CPL may cover the cathode CE, thereby preventing oxidation of the cathode CE. The capping layer CPL may be configured with an inorganic layer (or inorganic insulating layer) including an inorganic material.

An encapsulation layer TFE may be disposed on the capping layer CPL. The encapsulation layer TFE may prevent oxygen and/or moisture from infiltrating into a light emitting element layer. The encapsulation layer TFE may include a structure in which one or more inorganic layers and one or more organic layers are alternately stacked. For example, the inorganic layer may include silicon nitride, silicon oxide, silicon oxynitride (SiOₓN_{y}), or the like. For example, the organic layer may include an organic insulating material such as acrylic resin, epoxy resin, phenolic resin, polyamide resin, polyimide resin, unsaturated polyester resin, polyphenylene ether resin, polyphenylene sulfide resin, or benzocyclobutene (BCB). However, the material of the organic and inorganic layers of the encapsulation layer TFE are not necessarily limited thereto.

Light block layers BM1 and BM2 may be sequentially disposed on the encapsulation layer TFE. For example, a first light blocking layer BM1 may be disposed on the encapsulation layer TFE, and a second light blocking layer BM2 may be disposed on the first light blocking layer BM1. Although two light blocking layers BM1 and BM2 are configured in FIG. 8, the present disclosure is not necessarily limited thereto.

The light blocking layers BM1 and BM2 may include at least one light blocking unit. For example, each of the light blocking layers BM1 and BM2 may include at least two light blocking units. Accordingly, an opening OP may be formed between two light blocking units, and lights output through the anode AE, the light emitting layer EML, and the cathode CE may pass through the opening OP. At least some of the lights output through the anode AE, the light emitting layer EML, and the cathode CE may be controlled by the light blocking layers BM1 and BM2. For example, at least some of the corresponding lights may be absorbed in the light blocking layers BM1 and BM2. In some embodiments, the anode AE, the light emitting element EML, and the cathode CE, which are shown in FIG. 8, may constitute a light emitting element LD of the narrow pixel PXL_N shown in FIG. 6.

A first overcoat layer OC1 may be disposed between the first light blocking layer BM1 and the second light blocking layer BM2. A second overcoat layer OC2 may be disposed between the second light blocking layer BM2 and a light blocking layer disposed on the second light blocking layer BM2. Each of the first and second overcoat layers OC1 and OC2 may include various materials suitable for protecting lower layers from dust, moisture, and the like. For example, each of the first and second overcoat layers OC1 and OC2 may include at least one of an inorganic insulating layer and an organic insulating layer. For example, the first and second overcoat layers OC1 and OC2 may include epoxy, but the present disclosure is not necessarily limited thereto.

The light functional layer LFL shown in FIG. 5 may include at least one layer among the encapsulation layer TFE, the light blocking layers BM1 and BM2, and the overcoat layers OC1 and OC2. However, the present disclosure is not necessarily limited thereto.

In FIG. 9, a driving signal (or voltage) applied to the first narrow channel CHN_1 and the second narrow channel CHN_2 in accordance with an embodiment of the present disclosure is illustrated.

Referring to FIGS. 6 to 9, a first voltage V_B and a second voltage V_R may be alternately applied to the first narrow channel CHN_1. For example, the first voltage V_B and the second voltage V_R may be respectively applied to the (1_2)th light emitting unit EN_B and the (1_4)th light emitting unit EN_R, which overlap the first column CLM_N.

In accordance with a comparative example, a high voltage VGH_G and a low voltage VGL_G may be alternately applied to the second narrow channel CHN_2. For example, the high voltage VGH_G and the low voltage VGL_G may be respectively applied to the (1_3)th light emitting unit EN_G2 and the (2_1)th light emitting unit EW_G1. For example, the (1_3)th light emitting unit EN_G2 included in the narrow pixel PXL_N may emit light in the privacy mode, and the (2_1)th light emitting unit EW_G1 included in the wide pixel PXL_W might not emit light in the privacy mode. While voltages having different magnitudes are alternately applied to the second narrow channel CHN_2, power consumed in driving the display panel DP (see FIG. 4) may be increased.

In accordance with the embodiment of the present disclosure, while the driving voltage is prevented from being alternately applied to the second narrow channel CHN_2 and the second wide channel CHW_2, the power consumed in driving the display device DP can be decreased. For example, unlike the comparative example, the (1_3)th light emitting unit EN_G2 and the (2_1)th light emitting unit EW_G1 in accordance with the embodiment of the present disclosure can be individually driven. For example, the second narrow channel CHN_2 may be connected to the (1_1)th light emitting unit EN_G1 and the (1_3)th light emitting unit EN_G2. A first driving signal may be applied to the second narrow channel CHN_2. For example, when the display device DP is driven in the privacy mode, the low voltage VGL_G may be applied to the second narrow channel CHN_2.

The (2_1)th light emitting unit EW_G1 may be connected to the second wide channel CHW_2. For example, the second wide channel CHW_2 may be connected to the (2_1)th light emitting unit EW_G1 and the (2_3)th light emitting unit EW_G2. A second driving signal may be applied to the second wide channel CHW_2. When the display panel DP is driven in the privacy mode, the high voltage VGH_G may be applied to the second wide channel CHW_2. Accordingly, while toggle of a driving voltage applied to the second narrow channel CHN_2 and the second wide channel CHW_2 is prevented, the power consumption of the display panel DP can be reduced.

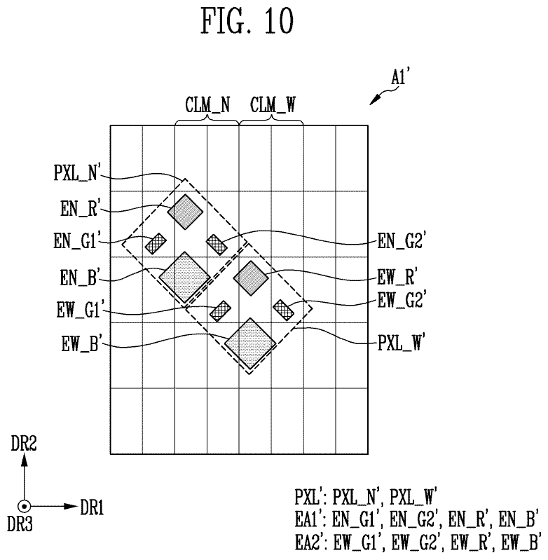

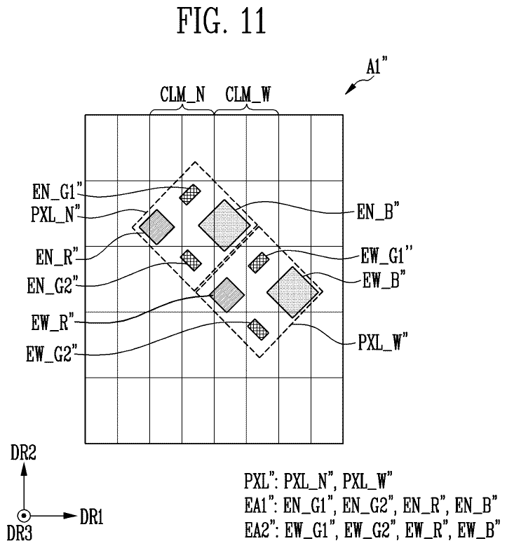

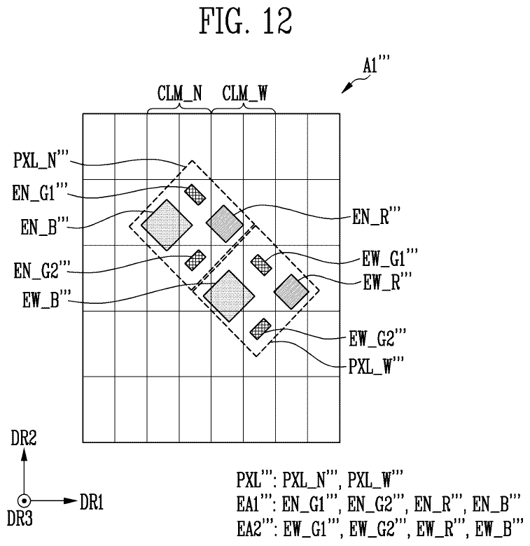

FIG. 10 is a plan view illustrating an embodiment of the pixels of the first area A1 shown in FIG. 4. FIG. 11 is a plan view illustrating an embodiment of the pixels of the first area A1 shown in FIG. 4. FIG. 12 is a plan view illustrating an embodiment of the pixels of the first area A1 shown in FIG. 4.

Referring to FIG. 10, a pixel PXL′ disposed on a first area A1′ may include a narrow pixel PXL_N′ and a wide pixel PXL_W′. The narrow pixel PXL_N′ and the wide pixel PXL_W′, which are shown in FIG. 10, may be described identically to the narrow pixel PXL_N and the wide pixel PXL_W, which are shown in FIG. 6. To the extent that an element is not described in detail with respect to this figure, it may be understood that the element is at least similar to a corresponding element that has been described elsewhere within the present disclosure.

The narrow pixel PXL N′ and the wide pixel PXL_W′ may include a first light emitting unit EA1′ and a second light emitting unit EA2′, respectively. A plurality of light emitting units EA1′ and EA2′ may be defined as not only an area in which a pixel electrode is exposed by an opening of a pixel defining layer, in a cross-sectional view, but also an area in which the exposed pixel electrode and a light emitting layer overlap each other, in a cross-sectional view.

Each of first light emitting units EA1′ may include a (1_1)th sub-light emitting unit EN_G1′, a (1_2)th sub-light emitting unit EN_R′, a (1_3)th sub-light emitting unit EN_G2′, and a (1_4)th sub-light emitting unit EN_B′. Each of second light emitting units EA2′ may include a (2_1)th sub-light emitting unit EW_G1′, a (2_2)th sub-light emitting unit EW_R′, a (2_3)th sub-light emitting unit EW_G2′, and a (2_4)th sub-light emitting unit EW_B′.

The (1_1)th sub-light emitting unit EN_G1′, the (1_3)th sub-light emitting unit EN_G2′, the (2_1)th sub-light emitting unit EW_G1′, and the (2_3)th sub-light emitting unit EW_G2′ may emit green light. The (1_2)th sub-light emitting unit EN_R′ and the (2_2)th sub-light emitting unit EW_R′ may emit red light. The (1_4)th sub-light emitting unit EN_B′ and the (2_4)th sub-light emitting unit EW_B′ may emit blue light. However, this is merely illustrative, and the present disclosure is not necessarily limited thereto.

The (1_1)th sub-light emitting unit EN_G1′ and the (1_3)th sub-light emitting unit EN_G2′ may be adjacent to each other in the first direction DR1. The (1_1)th sub-light emitting unit EN_G1′ and the (1_3)th sub-light emitting unit EN_G2′ may be symmetrically disposed. For example, in a plan view, (1_1)th sub-light emitting unit EN_G1′ and the (1_3)th sub-light emitting unit EN_G2′ may have a rectangular shape, and are symmetrically disposed with respect to the second direction DR2. In a plan view, the (1_1)th sub-light emitting unit EN_G1′ and the (1_3)th sub-light emitting unit EN_G2′ may have the same size. The (1_1)th sub-light emitting unit EN_G1′ may have a rectangular shape extending in a direction between the opposite direction of the first direction DR1 and the opposite direction of the second direction DR2, and the (1_3)th sub-light emitting unit EN_G2′ may have a rectangular shape extending in a direction between the first direction DR1 and the opposite direction of the second direction DR2.

The (1_2)th sub-light emitting unit EN_R′ and the (1_4)th sub-light emitting unit EN_B′ may be adjacent to each other in the second direction DR2. In a plan view, a size of the (1_4)th sub-light emitting unit EN_B′ may be larger than a size of the (1_2)th sub-light emitting unit EN_R′.

Shapes and arrangement relationships of the (2_1)th sub-light emitting unit EW_G1′, the (2_2)th sub-light emitting unit EW_R′, the (2_3)th sub-light emitting unit EW_G2′, and the (2_4)th sub-light emitting unit EW_B′, which are shown in FIG. 10, may be described identically to the shapes and arrangement relationships of the (1_1)th sub-light emitting unit EN_G1′, the (1_2)th sub-light emitting unit EN_R′, the (1_3)th sub-light emitting unit EN_G2′, and the (1_4)th sub-light emitting unit EN_B′, which are shown in FIG. 10. To the extent that an element is not described in detail with respect to this figure, it may be understood that the element is at least similar to a corresponding element that has been described elsewhere within the present disclosure.

Referring to FIGS. 6, 7, and 10, narrow channels CHN (see FIG. 7) may be disposed on the first column CLM_N, and wide channels CHW (see FIG. 7) may be disposed on the second column CLM_W.

The (1_1)th sub-light emitting unit EN_G1′ may be electrically connected to the second narrow channel CHN_2. For example, an anode AE (see FIG. 8) of the (1_1)th sub-light emitting unit EN_G1′ may be connected to a conductive terminal SDRU overlapping the second narrow channel CHN_2. The conductive terminal SDRU may correspond to the (1_1)th conductive terminal SDRU1_1 shown in FIG. 7, and are electrically connected to the second narrow channel CHN_2. Accordingly, the (1_1)th sub-light emitting unit EN_G1′ may be driven by a signal supplied from the second narrow channel CHN_2.

The (1_3)th sub-light emitting unit EN_G2′ may be electrically connected to the second narrow channel CHN_2. For example, an anode AE of the (1_3)th sub-light emitting unit EN_G2′ may be connected to a conductive terminal SDRU overlapping the second narrow channel CHN_2. The conductive terminal SDRU may correspond to the (1_3)th conductive terminal SDRU1_3 shown in FIG. 7, and are electrically connected to the second narrow channel CHN_2. Accordingly, the (1_3)th sub-light emitting unit EN_G2′ may be driven by a signal supplied from the second narrow channel CHN_2. That is, both the (1_1)th sub-light emitting unit EN_G1′ and the (1_3)th sub-light emitting unit EN_G2′ may emit light by a driving signal supplied by the second narrow channel CHN_2.

The (2_1)th sub-light emitting unit EW_G1′ may be electrically connected to the second wide channel CHW_2. For example, an anode AE of the (2_1)th sub-light emitting unit EW_G1′ may be connected to a conductive terminal SDRU overlapping the second wide channel CHW_2. The conductive terminal SDRU may be electrically connected to the second wide channel CHW_2. Accordingly, the (2_1)th sub-light emitting unit EW_G1′ may be driven by a signal supply from the second wide channel CHW_2. That is, although the (1_3)th sub-light emitting unit EN_G2′ and the (2_1)th sub-light emitting unit EW_G1′ are disposed side by side in the second direction DR2, the (1_3)th sub-light emitting unit EN_G2′ and the (2_1)th sub-light emitting unit EW_G1′ may be independently driven by the second narrow channel CHN_2 and the second wide channel CHW_2, respectively.

Referring to FIG. 11, a pixel PXL″ disposed on a first area A1″ may include a narrow pixel PXL_N″ and a wide pixel PXL_W″. The narrow pixel PXL_N″ and the wide pixel PXL_W″, which are shown in FIG. 11, may be described identically to the narrow pixel PXL_N and the wide pixel PXL_W, which are shown in FIG. 6. To the extent that an element is not described in detail with respect to this figure, it may be understood that the element is at least similar to a corresponding element that has been described elsewhere within the present disclosure.

The narrow pixel PXL_N″ and the wide pixel PXL_W″ may include a first light emitting unit EA1″ and a second light emitting unit EA2″, respectively. A plurality of light emitting units EA1″ and EA2″ may be defined as not only an area in which a pixel electrode is exposed by an opening of a pixel defining layer, in a cross-sectional view, but also an area in which the exposed pixel electrode and a light emitting layer overlap each other, in a cross-sectional view.

Each of first light emitting units EA1″ may include a (1_1)th sub-light emitting unit EN_R″, a (1_2)th sub-light emitting unit EN_G1″, a (1_3)th sub-light emitting unit EN_B″, and a (1_4)th sub-light emitting unit EN_G2″. Each of second light emitting units EA2″ may include a (2_1)th sub-light emitting unit EW_R″, a (2_2)th sub-light emitting unit EW_G1″, a (2_3)th sub-light emitting unit EW_B″, and a (2_4)th sub-light emitting unit EW_G2″.

The (1_2)th sub-light emitting unit EN_G1″, the (1_4)th sub-light emitting unit EN_G2″, the (2_2)th sub-light emitting unit EW_G1″, and the (2_4)th sub-light emitting unit EW_G2″ may emit green light. The (1_1)th sub-light emitting unit EN_R″ and the (2_1)th sub-light emitting unit EW_R″ may emit red light. The (1_3)th sub-light emitting unit EN_B″ and the (2_3)th sub-light emitting unit EW_B″ may emit blue light. However, this is merely illustrative, and the present disclosure is not necessarily limited thereto.

The (1_1)th sub-light emitting unit EN_R″ and the (1_3)th sub-light emitting unit EN_B″ may be adjacent to each other in the first direction DR1. The (1_1)th sub-light emitting unit EN_R″ and the (1_3)th sub-light emitting unit EN_B″ may be symmetrically disposed. For example, in a plan view, the (1_1)th sub-light emitting unit EN_R″ and the (1_3)th sub-light emitting unit EN_B″ may have a rhombic shape, and are symmetrically disposed with reference to the second direction DR2. In a plan view, a size of the (1_1)th sub-light emitting unit EN_R″ may be smaller than a size of the (1_3)th sub-light emitting unit EN_B″.

The (1_2)th sub-light emitting unit EN_G1″ and the (1_4)th sub-light emitting unit EN_G2″ may be adjacent to each other in the second direction DR2. In a plan view, the (1_2)th sub-light emitting unit EN_G1″ may have a rectangular shape extending in a direction between the first direction DR1 and the second direction DR2, and the (1_4)th sub-light emitting unit EN_G2″ may have a rectangular shape extending in a direction between the first direction DR1 and the opposite direction of the second direction DR2. On the plane, the (1_2)th sub-light emitting unit EN_G1″ and the (1_4)th sub-light emitting unit EN_G2″ may have the same size.

Shapes and arrangement relationships of the (2_1)th sub-light emitting unit EW_R″, the (2_2)th sub-light emitting unit EW_G1″, the (2_3)th sub-light emitting unit EW_B″, and the (2_4)th sub-light emitting unit EW_G2″, which are shown in FIG. 11, may be described identically to the shapes and arrangement relationships of the (1_1)th sub-light emitting unit EN_R″, the (1_2)th sub-light emitting unit EN_G1″, the (1_3)th sub-light emitting unit EN_B″, and the (1_4)th sub-light emitting unit EN_G2″, which are shown in FIG. 11. To the extent that an element is not described in detail with respect to this figure, it may be understood that the element is at least similar to a corresponding element that has been described elsewhere within the present disclosure.

Referring to FIGS. 6, 7, and 11, narrow channels CHN (see FIG. 7) may be disposed on the first column CLM_N, and wide channels CHW (see FIG. 7) may be disposed on the second column CLM_W.

The (1_1)th sub-light emitting unit EN_R″ may be electrically connected to the first narrow channel CHN_1. For example, an anode AE (see FIG. 8) of the (1_1)th sub-light emitting unit EN_R″ may be connected to a conductive terminal SDRU overlapping the first narrow channel CHN_1, and the corresponding conductive terminal SDRU may be electrically connected to the first narrow channel CHN_1. Accordingly, the (1_1)th sub-light emitting unit EN_R″ may be driven by a signal supplied from the first narrow channel CHN_1.

The (1_3)th sub-light emitting unit EN_B″ may be electrically connected to the first narrow channel CHN_1. For example, an anode AE (e.g., a (1_3)th anode) of the (1_3)th sub-light emitting unit EN_B″ may be connected to a conductive terminal SDRU which extends in the opposite direction of the first direction DR1 and the opposite direction of the second direction DR2 and overlaps the first narrow channel CHN_1. Accordingly, the corresponding conductive terminal SDRU may be electrically connected to the first narrow channel CHN_1. Accordingly, the (1_3)th sub-light emitting unit EN_B″ may be driven by a signal supplied from the first narrow channel CHN_1. That is, both the (1_1)th sub-light emitting unit EN_R″ and the (1_3)th sub-light emitting unit EN_B″ may emit light by a driving signal supplied from the first narrow channel CHN_1.

The (2_1)th sub-light emitting unit EW_R″ may be electrically connected to the first wide channel CHW_1. For example, an anode AE of the (2_1)th sub-light emitting unit EW_R″ may be connected to a conductive terminal SDRU overlapping the first wide channel CHW_1, and the corresponding conductive terminal SDRU may be electrically connected to the first wide channel CHW_1. Accordingly, the (2_1)th sub-light emitting unit EW_R″ may be driven by a signal supply from the first wide channel CHW_1. That is, although the (1_3)th sub-light emitting unit EN_B″ and the (2_1)th sub-light emitting unit EW_R″ are disposed side by side in the second direction DR2, the (1_3)th sub-light emitting unit EN_B″ and the (2_1)th sub-light emitting unit EW_R″ may be independently driven by the first narrow channel CHN_1 and the first wide channel CHW_1, respectively.

Referring to FIG. 12, a pixel PXL′″ disposed on a first area A1′″ may include a narrow pixel PXL_N′″ and a wide pixel PXL_W′″. The narrow pixel PXL_N′″ and the wide pixel PXL_W′″, which are shown in FIG. 12, may be described identically to the narrow pixel PXL_N and the wide pixel PXL_W, which are shown in FIG. 6. To the extent that an element is not described in detail with respect to this figure, it may be understood that the element is at least similar to a corresponding element that has been described elsewhere within the present disclosure.

The narrow pixel PXL_N′″ and the wide pixel PXL_W′″ may include a first light emitting unit EA1′″ and a second light emitting unit EA2′″, respectively. A plurality of light emitting units EA1′″ and EA2′″ may be defined as not only an area in which a pixel electrode is exposed by an opening of a pixel defining layer, in a cross-sectional view, but also an area in which the exposed pixel electrode and a light emitting layer overlap each other, in a cross-sectional view.

Each of first light emitting units EA1′″ may include a (1_1)th sub-light emitting unit EN_B′″, a (1_2)th sub-light emitting unit EN_G1′″, a (1_3)th sub-light emitting unit EN_R′″, and a (1_4)th sub-light emitting unit EN_G2′″. Each of second light emitting units EA2″ may include a (2_1)th sub-light emitting unit EW_B′″, a (2_2)th sub-light emitting unit EW_G1′″, a (2_3)th sub-light emitting unit EW_R′″, and a (2_4)th sub-light emitting unit EW_G2′″.

The (1_2)th sub-light emitting unit EN_G1′″, the (1_4)th sub-light emitting unit EN_G2′″, the (2_2)th sub-light emitting unit EW_G1′″, and the (2_4)th sub-light emitting unit EW_G2′″ may emit green light. The (1_1)th sub-light emitting unit EN_B′″ and the (2_1)th sub-light emitting unit EW_B′″ may emit blue light. The (1_3)th sub-light emitting unit EN_R′″ and the (2_3)th sub-light emitting unit EW_R′″ may emit red light. However, this is merely illustrative, and the present disclosure is not necessarily limited thereto.

The (1_1)th sub-light emitting unit EN_B′″ and the (1_3)th sub-light emitting unit EN_R′″ may be adjacent to each other in the first direction DR1. The (1_1)th sub-light emitting unit EN_B′″ and the (1_3)th sub-light emitting unit EN_R′″ may be symmetrically disposed. For example, in a plan view, the (1_1)th sub-light emitting unit EN_B′″ and the (1_3)th sub-light emitting unit EN_R′″ may have a rhombic shape, and are symmetrically disposed with reference to the second direction DR2. In a plan view, a size of the (1_1)th sub-light emitting unit EN_B′″ may be larger than a size of the (1_3)th sub-light emitting unit EN_R′″.

The (1_2)th sub-light emitting unit EN_G1′″ and the (1_4)th sub-light emitting unit EN_G2′″ may be adjacent to each other in the second direction DR2. In a plan view, the (1_2)th sub-light emitting unit EN_G1′″ may have a rectangular shape extending in a direction between the opposite direction of the first direction DR1 and the second direction DR2, and the (1_4)th sub-light emitting unit EN_G2′″ may have a rectangular shape extending in a direction between the opposite direction of the first direction DR1 and the opposite direction of the second direction DR2. On the plane, the (1_2)th sub-light emitting unit EN_G1′″ and the (1_4)th sub-light emitting unit EN_G2′″ may have the same size.

Shapes and arrangement relationships of the (2_1)th sub-light emitting unit EW_B′″, the (2_2)th sub-light emitting unit EW_G1′″, the (2_3)th sub-light emitting unit EW_R′″, and the (2_4)th sub-light emitting unit EW_G2′″, which are shown in FIG. 12, may be described identically to the shapes and arrangement relationships of the (1_1)th sub-light emitting unit EN_B′″, the (1_2)th sub-light emitting unit EN_G1′″, the (1_3)th sub-light emitting unit EN_R′″, and the (1_4)th sub-light emitting unit EN_G2′″, which are shown in FIG. 12. To the extent that an element is not described in detail with respect to this figure, it may be understood that the element is at least similar to a corresponding element that has been described elsewhere within the present disclosure.

Referring to FIGS. 6, 7, and 12, narrow channels CHN (see FIG. 7) may be disposed on the first column CLM_N, and wide channels CHW (see FIG. 7) may be disposed on the second column CLM_W.

The (1_1)th sub-light emitting unit EN_B′″ may be electrically connected to the first narrow channel CHN_1. For example, an anode AE (see FIG. 8) of the (1_1)th sub-light emitting unit EN_B′″ may be connected to a conductive terminal SDRU overlapping the first narrow channel CHN_1, and the corresponding conductive terminal SDRU may be electrically connected to the first narrow channel CHN_1. Accordingly, the (1_1)th sub-light emitting unit EN_B′″ may be driven by a signal supplied from the first narrow channel CHN_1.

The (1_3)th sub-light emitting unit EN_R′″ may be electrically connected to the first narrow channel CHN_1. For example, an anode AE (e.g., a (1_3)th anode) of the (1_3)th sub-light emitting unit EN_R′″ may be connected to a conductive terminal SDRU which extends in the opposite direction of the first direction DR1 and the opposite direction of the second direction DR2 and overlaps the first narrow channel CHN_1. Accordingly, the corresponding conductive terminal SDRU may be electrically connected to the first narrow channel CHN_1. Accordingly, the (1_3)th sub-light emitting unit EN_R′″ may be driven by a signal supplied from the first narrow channel CHN_1. That is, both the (1_1)th sub-light emitting unit EN_B′″ and the (1_3)th sub-light emitting unit EN_R′″ may emit light by a driving signal supplied from the first narrow channel CHN_1.

The (2_1)th sub-light emitting unit EW_B′″ may be electrically connected to the first wide channel CHW_1. For example, an anode AE of the (2_1)th sub-light emitting unit EW_B′″ may be connected to a conductive terminal SDRU overlapping the first wide channel CHW_1, and the corresponding conductive terminal SDRU may be electrically connected to the first wide channel CHW_1. Accordingly, the (2_1)th sub-light emitting unit EW_G′″ may be driven by a signal supply from the first wide channel CHW_1. That is, although the (1_3)th sub-light emitting unit EN_R′″ and the (2_1)th sub-light emitting unit EW_B′″ are disposed side by side in the second direction DR2, the (1_3)th sub-light emitting unit EN_R′″ and the (2_1)th sub-light emitting unit EW_B′″ may be independently driven by the first narrow channel CHN_1 and the first wide channel CHW_1, respectively.

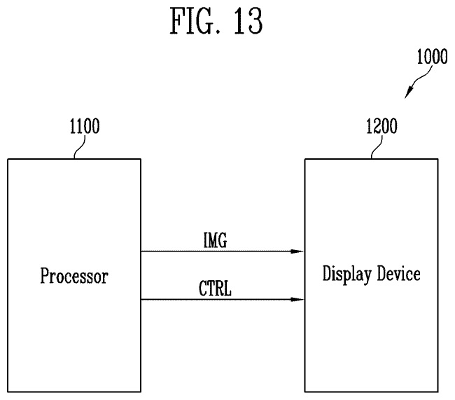

FIG. 13 is a block diagram illustrating an embodiment of a display system.

Referring to FIG. 13, the display system 1000 may include a processor 1100 and a display device 1200.

The processor 1100 may perform various tasks and various calculations. In embodiments, the processor 1100 may include an Application Processor (AP), a Graphics Processing Unit (GPU), a microprocessor, a Central Processing Unit (CPU), and the like. The processor 1100 may be connected to other components of the display system 1000 through a bus system to control the components of the display system 1000.

The processor 1100 may transmit image data IMG and a control signal CTRL to the display device 1200. The display device 1200 may display an image, based on the image data IMG and the control signal CTRL. The display device 1200 may be configured identically to the display device DD described with reference to FIG. 1. The image data IMG and the control signal CTRL may be provided as the input image data IMG and the control signal CTRL, which are shown in FIG. 1, respectively.

The display system 1000 may include a computing system for providing an image display function, such as a smart watch, a mobile phone, a smartphone, a portable computer, a tablet personal computer (PC), a watch phone, an automotive display, a smart glass, a portable multimedia player (PMP), a navigation system, or an ultra mobile computer (UMPC). The display system 1000 may include at least one of a head mounted display (HMD) device, a virtual reality (VR) device, a mixed reality (MR) device, and an augmented reality (AR) device.

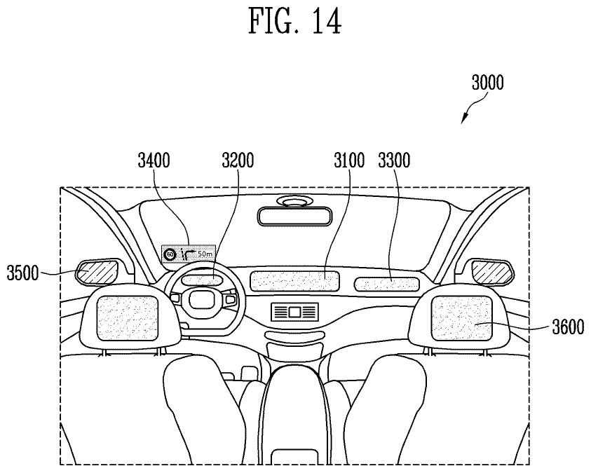

FIG. 14 is a perspective view illustrating an application example of the display system shown in FIG. 13.

Referring to FIG. 14, the display system 1000 shown in FIG. 13 may be applied to an automotive display system 3000. The automotive display system 3000 may include a computing system provided at the inside/outside of a vehicle to provide image data.

For example, the display system 1000 and/or the display device 1200 may be applied to at least one of an infotainment panel 3100, a cluster 3200, a co-driver display 3300, a head-up display 3400, a side mirror display 3500, and a rear seat display 3600, which are provided in the vehicle. However, the embodiment shown in FIG. 14 is merely illustrative, and the present disclosure is not necessarily limited thereto. For example, the display system 1000 and/or the display device 1200 may be applied to smart glasses, VR/AR devices, and the like.

In the display device and the display system, in accordance with the present disclosure, power consumption of the display device is reduced or minimized, and degradation of the display panel is minimized, thereby increasing the reliability of the display device.

Example embodiments have been disclosed herein, and although specific terms are employed, they are used and are to be interpreted in a generic and descriptive sense and not necessarily for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure.

What is claimed is:

1. A display device, comprising:
a display panel including a narrow pixel that includes a first light emitting unit and a wide pixel that includes a second light emitting unit; and
at least one channel disposed on the display panel, the at least one channel configured to provide a driving signal to the narrow pixel and the wide pixel,
wherein the first light emitting unit includes a (1_1)th sub-light emitting unit and a (1_3) th sub-light emitting unit, which are adjacent to each other in a first direction, and
wherein the at least one channel includes a narrow channel which provides a first driving signal to the (1_1)th sub-light emitting unit and the (1_3)th sub-light emitting unit.

2. The display device of claim 1, wherein the wide pixel is configured to emit light in a normal mode, and the narrow pixel is configured to emit light in a privacy mode.

3. The display device of claim 2, wherein the first driving signal has a constant value in the privacy mode.

4. The display device of claim 3, wherein the second light emitting unit includes a (2_1) th sub-light emitting unit adjacent to the (1_3)th sub-light emitting unit in a second direction intersecting the first direction, and
wherein the (2_1)th sub-light emitting unit emits light, based on a second driving signal that is different from the first driving signal.

5. The display device of claim 4, wherein the second light emitting unit includes a (2_3)th sub-light emitting unit adjacent to the (2_1)th sub-light emitting unit in the first direction, and
wherein the at least one channel includes a wide channel which provides the second driving signal to the (2_1)th sub-light emitting unit and the (2_3)th sub-light emitting unit.

6. The display device of claim 5, wherein the display panel includes:
a substrate;
a pixel circuit layer disposed on the substrate, the pixel circuit layer including at least one transistor; and
a display element layer disposed on the pixel circuit layer, the display element layer including the first light emitting unit and the second light emitting unit, and
wherein the pixel circuit layer includes a conductive terminal which electrically connects the at least one transistor to an anode of any one of the first light emitting unit and the second light emitting unit.

7. The display device of claim 6, wherein the conductive terminal includes:
a (1_1)th conductive terminal connected to a (1_1)th anode of the (1_1)th sub-light emitting unit; and
a (1_3)th conductive terminal connected to a (1_3)th anode of the (1_3)th sub-light emitting unit,
wherein, in a plan view, the (1_1)th conductive terminal and the (1_3)th conductive terminal overlap the narrow channel.

8. The display device of claim 7, wherein the (1_1)th anode includes a first anode bridge extending in a direction toward the (1_1)th conductive terminal.

9. The display device of claim 1, further comprising a data driver configured to supply a data signal to the display panel,
wherein the at least one channel is a data line extending from the data driver.

10. The display device of claim 1, wherein each of the narrow pixel and the wide pixel is arranged in a second direction intersecting the first direction.

11. The display device of claim 1, wherein the (1_1)th sub-light emitting unit and the (1_3)th sub-light emitting unit emit light of a first color.

12. The display device of claim 11, wherein the narrow pixel includes a (1_2)th sub-light emitting unit and a (1_4)th sub-light emitting unit, which are adjacent to each other in a second direction intersecting the first direction, and
wherein the (1_2)th sub-light emitting unit emits light of a second color that is different from the first color, and the (1_4)th sub-light emitting unit emits light of a third color that is different from the first color and the second color.

13. The display device of claim 12, wherein, in a plan view, the (1_1)th sub-light emitting unit and the (1_3)th sub-light emitting unit each have a rectangular shape, and the (1_2)th sub-light emitting unit and the (1_4)th sub-light emitting unit each have a rhombic shape.

14. The display device of claim 13, wherein, in a plan view, an area of the (1_4)th sub-light emitting unit is wider than an area of the (1_2)th sub-light emitting unit, and the area of the (1_2)th sub-light emitting unit is wider than an area of each of the (1_1)th sub-light emitting unit and the (1_3)th sub-light emitting unit.

15. The display device of claim 7, wherein the (1_1)th sub-light emitting unit emits light of a second color, and the (1_3)th sub-light emitting unit emits light of a third color that is different from the second color.

16. The display device of claim 15, wherein the narrow pixel includes a (1_2)th sub-light emitting unit and a (1_4)th sub-light emitting unit, which are adjacent to each other in the second direction, and
wherein the (1_2)th sub-light emitting unit and the (1_4)th sub-light emitting unit emit light of a first color that is different from the second color and the third color.

17. The display device of claim 16, wherein the (1_3)th anode extends in an opposite direction of the first direction and the second direction to be in contact with the (1_3)th conductive terminal.

18. A display system, comprising:
a processor; and
a display device configured to display an image based on input image data provided from the processor,
wherein the display device includes:
a display panel including a narrow pixel including a first light emitting unit and a wide pixel including a second light emitting unit; and
at least one channel disposed on the display panel, the at least one channel configured to provide a driving signal to the narrow pixel and the wide pixel,
wherein the first light emitting unit includes a (1_1)th sub-light emitting unit and a (1_3)th sub-light emitting unit, which are adjacent to each other in a first direction, and
wherein the at least one channel includes a narrow channel which provides a first driving signal to the (1_1)th sub-light emitting unit and the (1_3)th sub-light emitting unit.

19. The display system of claim 18, wherein the wide pixel is configured to emit light in a normal mode, and the narrow pixel is configured to emit light in a privacy mode.

20. The display system of claim 19, wherein the first driving signal has a constant value in the privacy mode.
